(19) United States
(12) Patent Application Publication
(10) Pub. No.: US 2015/0232979 A1
(43) Pub. Date: Aug. 20, 2015

(54) FERROELECTRIC FILM AND MANUFACTURING METHOD THEREOF

(71) Applicant: YOUTEC CO., LTD., Chiba (JP)

(72) Inventors: Takeshi KIJIMA, Chiba (JP); Yuuji HONDA, Chiba (JP)

(21) Appl. No.: 14/620,519

(22) Filed: Feb. 12, 2015

(30) Foreign Application Priority Data
Feb. 18, 2014 (JP) 2014-028923

(51) Int. Cl. C23C 14/08; C23C 14/34

(52) U.S. Cl. CPC C23C 14/088; C23C 14/34

(57) ABSTRACT

To provide a ferroelectric film having improved uniformity in the composition of the film surface and the composition of the entire film, or a manufacturing method thereof. An aspect of the present invention is a ferroelectric film including a ferroelectric coated and sintered crystal film; and a ferroelectric crystal film formed on the ferroelectric coated and sintered crystal film, by a sputtering method, wherein the ferroelectric coated and sintered crystal film is formed by coating a solution having a metal compound containing, in an organic solvent, all of or a part of constituent metals of the ferroelectric crystal film and a partial polycondensation product thereof and by heating the same to be crystallized.

### BACKGROUND OF THE INVENTION

1. Field of the Invention

The present invention relates to a ferroelectric film and a manufacturing method thereof.

2. Description of a Related Art

FIG. 3 is a cross-sectional view for explaining a conventional manufacturing method of a ferroelectric crystal film.

A Pt film 102 oriented in (100) on a substrate 101 such as a 4-inch wafer is formed. Subsequently, a Pb(Zr,Ti)O₃ film (hereinafter, referred to as a “PZT film”) 103 is epitaxially grown on the Pt film 102, by a sputtering method. An example of sputtering conditions at this time is as follows.

[Sputtering Conditions]

Apparatus: RF magnetron sputtering apparatus

Power: 1500 W

Gas: Ar/O₂

Pressure: 0.14 Pa

Temperature: 600° C.

Film formation rate: 0.63 nm/sec

Film formation time: 53 min

According to the above-described epitaxial growth, a PZT film 103 having a thickness of 2.5 μm is formed on the Pt film 102.

In the conventional manufacturing method of a ferroelectric crystal film, since the PZT film 103 is formed by epitaxial growth by sputtering, the compositions of the surface and the whole of the PZT film 103 are different largely from each other. Consequently, it is considered that the PZT film 103 by sputtering results in having a large density of a leak current and a low breakdown voltage.

[Patent Literature 1] Japanese Patent Laid-Open No. 2013-251490

### SUMMARY OF THE INVENTION

One aspect of the present invention is to provide a ferroelectric film having improved uniformity in the composition of the film surface and the composition of the entire film, or a manufacturing method thereof.

Hereinafter, various aspects of the present invention will be explained.

[1]A ferroelectric film, comprising:

a ferroelectric coated and sintered crystal film; and

a ferroelectric crystal film formed on the ferroelectric coated and sintered crystal film, by a sputtering method,

wherein

the ferroelectric coated and sintered crystal film is formed by coating a solution having a metal compound containing, in an organic solvent, all of or a part of constituent metals of the ferroelectric crystal film and a partial polycondensation product thereof and by heating the same to be crystallized.

[2] The ferroelectric film according to [1], wherein each of the ferroelectric coated and sintered crystal film and the ferroelectric crystal film is a Pb(Zr,Ti)O₃ film or a (Pb,A)(Zr,Ti)O₃ film, and A includes at least one kind selected from the group consisting of Li, Na, K, Rb, Ca, Sr, Ba, Bi and La.

[3] The ferroelectric film according to [2], wherein, when a result of SIMS analysis of a composition of a surface of said ferroelectric crystal film gives a Pb content of P₁ mol %, a Zr content of Z₁ mol % and a Ti content of T₁ mol % and a result of ICP analysis of a total composition of said ferroelectric coated and sintered crystal film and said ferroelectric crystal film gives a Pb content of P₂ mol %, a Zr content of Z₂ mol % and a Ti content of T₂ mol %, the contents satisfy formulae 1 to 3 below,

0.8×P₂≦P₁≦1.2×P₂ formula 1

0.8×Z₂≦Z₁≦1.2×Z₂ formula 2

0.8×T₂≦T₁≦1.2×T₂ formula 3.

[4] The ferroelectric film according to [2] or [3], wherein:

a total thickness of said ferroelectric coated and sintered crystal film and said ferroelectric crystal film is from 0.5 μm or more to less than 1.75 μm; and

a composition ratio of Zr to Ti in the whole of said ferroelectric coated and sintered crystal film and said ferroelectric crystal film satisfies a formula 4 below,

51/49≧Zr/Ti≧40/60 formula 4.

[5] The ferroelectric film according to [2] or [3], wherein:

a total thickness of said ferroelectric coated and sintered crystal film and said ferroelectric crystal film is from 1.75 μm or more to 5 μm or less; and

a composition ratio of Zr to Ti in the whole of said ferroelectric coated and sintered crystal film and said ferroelectric crystal film satisfies a formula 5 below,

54/46≦Zr/Ti≦60/40 formula 5.

[6] The ferroelectric film according to [5], wherein a total thickness of said ferroelectric coated and sintered crystal film and said ferroelectric crystal film is 3.5 μm or less.

[7] The ferroelectric film according to any one of [1] to [6], wherein said ferroelectric coated and sintered crystal film has a thickness of 20 nm or more to less than 500 nm.

[8] The ferroelectric film according to any one of [1] to [7], wherein said ferroelectric crystal film is oriented in a same plane as that of said ferroelectric coated and sintered crystal film.

[9]A manufacturing method of a ferroelectric film, comprising the steps of:
forming an amorphous precursor film by a method of coating a solution;
forming a ferroelectric coated and sintered crystal film, by heating the amorphous precursor film in an oxygen atmosphere to thereby oxidize and crystallize the amorphous precursor film; and

epitaxially growing and forming a ferroelectric crystal film on the ferroelectric coated and sintered crystal film, by a sputtering method, wherein the solution is a solution containing, in an organic solvent, a metal compound including all of or a part of constituent metals of the ferroelectric crystal film and a partial polycondensation product thereof.

[10] The manufacturing method of a ferroelectric film according to [9], wherein each of said ferroelectric coated and sintered crystal film and said ferroelectric crystal film is a Pb(Zr,Ti)O₃ film or a (Pb,A)(Zr,Ti)O₃ film, and A includes at least one kind selected from the group consisting of Li, Na, K, Rb, Ca, Sr, Ba, Bi and La.

[11] The manufacturing method of a ferroelectric film according to [10], when a result of SIMS analysis of a composition of a surface of said ferroelectric crystal film gives a Pb content of P₁ mol %, a Zr content of Z₁ mol % and a Ti content of T₁ mol % and a result of ICP analysis of a total composition of said ferroelectric coated and sintered crystal film and said ferroelectric crystal film gives a Pb content of P₂ mol %, a Zr content of Z₂ mol % and a Ti content of T₂ mol %, the contents satisfy formulae 1 to 3 below,

0.8×P₂≦P₁≦1.2×P₂ formula 1

0.8×Z₂≦Z₁≦1.2×Z₂ formula 2

0.8×T₂≦T₁≦1.2×T₂ formula 3.

[12] The manufacturing method of a ferroelectric film according to [10] or [11], wherein a temperature in forming said ferroelectric crystal film by a sputtering method is lower than a temperature in oxidizing and crystallizing said amorphous precursor film, by 150° C. or more.

[13] The manufacturing method of a ferroelectric film according to any one of [10] to [12], wherein:

a total thickness of said ferroelectric coated and sintered crystal film and said ferroelectric crystal film is from 0.5 m or more to less than 1.75 μm; and

a composition ratio of Zr to Ti in the whole of said ferroelectric coated and sintered crystal film and said ferroelectric crystal film satisfies a formula 4 below,

51/49≧Zr/Ti≧40/60 formula 4.

[14] The manufacturing method of a ferroelectric film according to any one of [10] to [12], wherein:

a total thickness of said ferroelectric coated and sintered crystal film and said ferroelectric crystal film is from 1.75 μm or more to 5 μm or less; and a composition ratio of Zr to Ti in the whole of said ferroelectric coated and sintered crystal film and said ferroelectric crystal film satisfies a formula 5 below,

54/46≦Zr/Ti≦60/40 formula 5.

[15] The manufacturing method of a ferroelectric film according to [14], wherein a total thickness of said ferroelectric coated and sintered crystal film and said ferroelectric crystal film is 3.5 μm or less.

[16] The manufacturing method of a ferroelectric film according to any one of [9] to [15], wherein a thickness of said ferroelectric coated and sintered crystal film is from 20 nm or more to less than 500 nm.

[17] The manufacturing method of a ferroelectric film according to any one of [9] to [16], wherein said ferroelectric coated and sintered crystal film is oriented in a same plane as that of said ferroelectric crystal film.

By applying one aspect of the present invention, there can be provided a ferroelectric film in which the uniformity in the composition of the film surface and the entire film has been enhanced.

### BRIEF DESCRIPTION OF THE DRAWINGS

FIG. 1 is a schematic cross-sectional view explaining a manufacturing method of a ferroelectric film according to one aspect of the present invention.

FIG. 2 is a drawing showing results of evaluating crystallinity of a spin-coated PZT film and a sputtered PZT film of a sample in Example by XRD.

FIG. 3 is a cross-sectional view for explaining a manufacturing method of a conventional ferroelectric crystal film.

### DESCRIPTION OF THE PREFERRED EMBODIMENTS

Hereinafter, embodiments and Examples of the present invention will be explained in detail using the drawings. However, a person skilled in the art would be able to easily understand that the present invention is not limited to the following explanations but forms and details thereof may be variously modified, without deviating from the purport and the scope of the present invention. Accordingly, the present invention is not to be construed as being limited to the description of the embodiments and Examples, shown below.

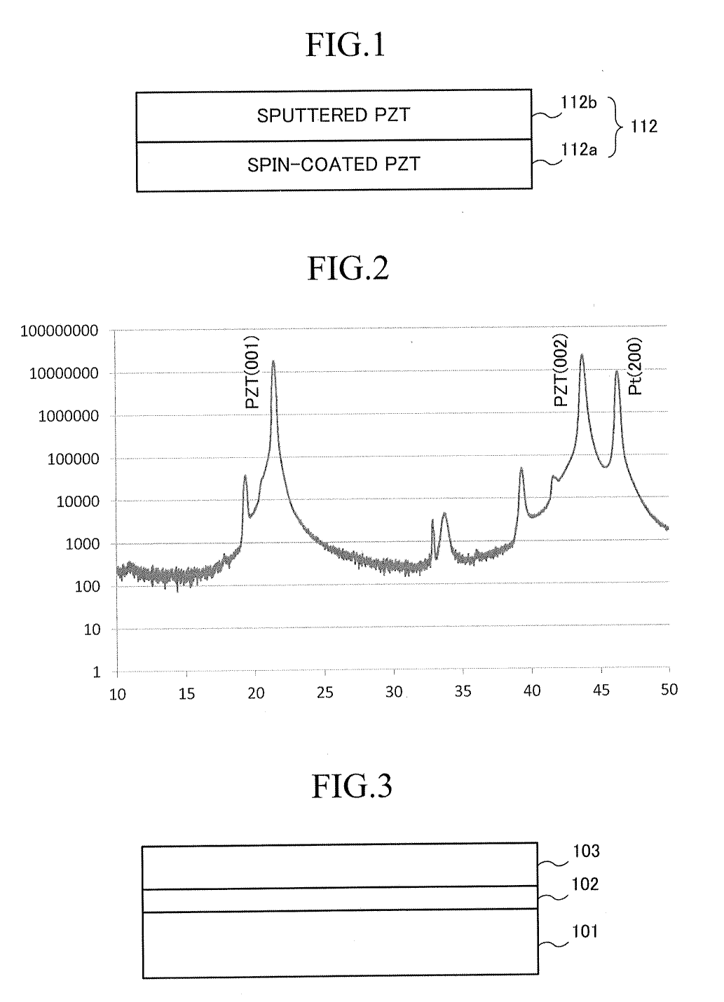

FIG. 1 is a schematic cross-sectional view explaining a manufacturing method of a ferroelectric film according to one aspect of the present invention.

A substrate (not shown) is prepared. Various kinds of substrates can be used as the substrate, and there can be used, for example, substrates of a single crystal such as a Si single crystal or a sapphire single crystal, substrates of a single crystal with a metal oxide film formed on the surface thereof, substrates with a polysilicon film or a silicide film formed on the surface thereof, and the like.

Note that, in the present embodiment, a Si substrate oriented in (100) is used.

Next, a ZrO₂ film (not shown) is formed on the Si substrate at a temperature of 550° C. or less (preferably at 500° C.) by an evaporation method. The ZrO₂ film is oriented in (200).

After that, a Pt film (not shown) by epitaxial growth is formed on the ZrO₂ film at a temperature of 550° C. or less (preferably at 400° C.) by sputtering. The Pt film is oriented in (200). Note that the Pt film can be functioned as an electrode film. Furthermore, the Pt film may be an electrode film other than a Pt film. The electrode film may be an electrode film formed of, for example, an oxide or metal, or may be an Ir film.

By setting the substrate temperature to be 550° C. or less when forming the ZrO₂ film and the Pt film and controlling the growth rate and thermal stress of the film to be low, as described above, it is possible to orient the Pt film in (200) even when forming the Pt film directly on a ZrO₂ film without the mixing of Y₂O₃.

Next, a first Sr(Ti₁₋ₓRuₓ)O₃ film (not shown) is formed on the Pt film by sputtering. Note that the x satisfies a formula 1 below. Furthermore, a sintered body of a Sr(Ti₁₋ₓRuₓ)O₃ is used as a sputtering target at this time.

However, the x satisfies the formula 1 below.

0.01≦x≦0.4 (preferably 0.05≦x≦0.2) formula 1

Note that the reason why the x in the first Sr(Ti₁₋ₓRuₓ)O₃ film is 0.4 or less is because, when the x is set to exceed 0.4, the first Sr(Ti₁₋ₓRuₓ)O₃ film becomes powdery and cannot sufficiently be solidified.

After that, the first Sr(Ti₁₋ₓRuₓ)O₃ film (not shown) is crystallized by RTA (Rapid Thermal Anneal) in a pressurized oxygen atmosphere.

The first Sr(Ti₁₋ₓRuₓ)O₃ film is a film of a complex oxide of strontium, titanium and ruthenium, the complex oxide being a compound having a perovskite structure.

Note that, in the present embodiment, the Pt film is made to function as an electrode film, but the first Sr(Ti₁₋ₓRuₓ)O₃ film can be made to function as an electrode film by forming the first Sr(Ti₁₋ₓRuₓ)O₃ film to be thick without forming the Pt film.

Next, as shown in FIG. 1, a ferroelectric film 112 is formed on the first Sr(Ti₁₋ₓRuₓ)O₃ film. Specifically, a ferroelectric coated and sintered crystal film 112a is formed on the first Sr(Ti₁₋ₓRuₓ)O₃ film, and a ferroelectric crystal film 112b is formed on the ferroelectric coated and sintered crystal film 112a.

The formation of the ferroelectric coated and sintered crystal film 112a is carried out by forming, on the first Sr(Ti₁₋ₓRuₓ)O₃ film, the amorphous precursor film by a method of coating a solution, and by heating the resultant amorphous precursor film to a temperature of 650° C. or more in an oxygen atmosphere to thereby oxidize and crystallize the amorphous precursor film. The solution is a solution containing, in an organic solvent, a metal compound including the whole of or a part of constituent metals of the ferroelectric crystal film 112b and a partial polycondensation product thereof.

The ferroelectric crystal film 112b is formed on the ferroelectric coated and sintered crystal film 112a, by epitaxial growth at a temperature of 500° C. or less (for example 450° C.) by a sputtering method. Note that the temperature when forming the ferroelectric crystal film 112b can be set to be lower by 150° C. or more than the temperature when oxidizing and crystallizing the above-described amorphous precursor film.

A specific example of each of the ferroelectric coated and sintered crystal film 112a and the ferroelectric crystal film 112b is a Pb(Zr,Ti)O₃ film or a (Pb,A)(Zr,Ti)O₃ film, where A includes at least one kind selected from the group consisting of Li, Na, K, Rb, Ca, Sr, Ba, Bi and La. At this time, when a result of SIMS analysis of the composition of a surface of the ferroelectric crystal film 112b gives a Pb content of P₁ mol %, a Zr content of Z₁ mol % and a Ti content of T₁ mol % and a result of ICP analysis of the composition of the whole ferroelectric coated and sintered crystal film 112a and ferroelectric crystal film 112b gives a Pb content of P₂ mol %, a Zr content of Z₂ mol % and a Ti content of T₂ mol %, the contents satisfy formulae 1 to 3 below, preferably satisfy formulae 1′ to 3′ below.

0.8×P₂≦P₁≦1.2×P₂ formula 1

0.8×Z₂≦Z₁≦1.2×Z₂ formula 2

0.8×T₂≦T₁≦1.2×T₂ formula 3

0.9×P₂≦P₁≦1.1×P₂ formula 1′

0.9×Z₂≦Z₁≦1.1×Z₂ formula 2′

0.9×T₂≦T₁≦1.1×T₂ formula 3′

Note that, in the present specification, a “Pb(Zr,Ti)O₃ film or (Pb,A)(Zr,Ti)O₃ film” also includes a film of a pure composition containing an impurity therein, and it is assumed that various impurities can be incorporated as long as the function of the piezoelectric body of a Pb(Zr,Ti)O₃ film or a (Pb,A)(Zr,Ti)O₃ film is not extinguished even when the impurity is incorporated.

When the total thickness of the ferroelectric coated and sintered crystal film 112a and the ferroelectric crystal film 112b is from 0.5 μm or more to less than 1.75 μm (preferably from 0.5 μm or more to 1.5 μm or less), it is preferable to set the composition ratio of Zr to Ti in the whole of the ferroelectric coated and sintered crystal film 112a and the ferroelectric crystal film 112b to be a tetragonal film composition satisfying a formula 4 below.

The reason thereof will be described later.

51/49≧Zr/Ti≧40/60 formula 4

Furthermore, when the total thickness of the ferroelectric coated and sintered crystal film 112a and the ferroelectric crystal film 112b is from 1.75 μm or more to 5 μm or less (preferably from 2 μm or more to 5 μm or less, more preferably from 2 μm or more to 3.5 μm or less), it is preferable to set the composition ratio of Zr to Ti in the whole of the ferroelectric coated and sintered crystal film 112a and the ferroelectric crystal film 112b to be a rhombohedral film composition satisfying a formula 5 below. The reason thereof will be described later.

54/46≦Zr/Ti≦60/40 formula 5

For example, in a case of a bulk state, PZT is classified into a hard PZT and a soft PZT. They are used in the meaning of being literally hard or soft. There is no precise definition and they are classified on the basis of Tc, Vc and the like, and those having not opened and thin hysteresis are referred to as soft ones and those having squarely and largely opened hysteresis are referred to as hard ones. When the definition is applied to the thin film PZT of the present embodiment, the Zr-rich PZT shown by the above formula 5 is a soft PZT and the Ti-rich PZT shown by the above formula 4 is a hard PZT.

Namely, a soft material means a material having a small high voltage Vc and a closed P-E hysteresis shape as ferroelectric properties, and a hard material means a material having a large high voltage Vc and an opened P-E hysteresis shape. Accordingly, in a thin film PZT, the case where Zr is richer than 52/48 (MPB) at a Zr/Ti ratio and the P-E hysteresis shape is closed is referred to as a soft material, and the case where Ti is richer than 52/48 (MPB) and the P-E hysteresis shape is opened is referred to as a hard material. From these, when the total thickness of the ferroelectric coated and sintered crystal film 112a and the ferroelectric crystal film 112b is as small as 0.5 m or more to less than 1.75 μm (preferably 0.5 μm or more to 1.5 μm or less), a certain level of hardness of the entire film is preferably kept through the use of a hard material. Furthermore, when the total thickness of the ferroelectric coated and sintered crystal film 112a and the ferroelectric crystal film 112b is as large as from 1.75 m or more to 5 μm or less (preferably 2 m or more to 5 μm or less, more preferably from 2 μm or more to 3.5 μm or less), the entire film is preferably prevented from becoming too hard through the use of a soft material.

The thickness of the ferroelectric coated and sintered crystal film 112a is preferably 20 nm or more to less than 500 nm.

After forming the ferroelectric crystal film 112b on the ferroelectric coated and sintered crystal film 112a, a second Sr(Ti₁₋ₓRuₓ)O₃ film is formed on the ferroelectric crystal film 112b, by sputtering. Note that x satisfies a formula 1 below. In addition, sputtering conditions at this time are the same as those for the first Sr(Ti₁₋ₓRuₓ)O₃ film.

0.01≦x≦0.4 (preferably 0.05≦x≦0.2) formula 1

Then, the second Sr(Ti₁₋ₓRuₓ)O₃ film is crystallized by RTA in a pressurized oxygen atmosphere. RTA conditions at this time are the same as those for the first Sr(Ti₁₋ₓRuₓ)O₃ film.

According to the present embodiment, the formation of the ferroelectric coated and sintered crystal film 112a is carried out by forming an amorphous precursor film through a method of coating a solution onto the first Sr(Ti₁₋ₓRuₓ)O₃ film and by heating the amorphous precursor film to a temperature of 650° C. or more in an oxygen atmosphere to thereby oxidize and crystallize the amorphous precursor film. In this way, epitaxial growth is carried out at a temperature of 500° C. or less by a sputtering method to thereby form the ferroelectric crystal film 112b on the ferroelectric coated and sintered crystal film 112a having been crystallized. Namely, initial nuclei and crystal nuclei have already been formed by the ferroelectric coated and sintered crystal film 112a, in forming the ferroelectric crystal film 112b by sputtering, and thus the ferroelectric crystal film 112b with excellent crystallinity can be formed even when the temperature in forming the ferroelectric crystal film 112b is set to be as low as 500° C. or less. Furthermore, the ferroelectric crystal film 112b can be oriented in the same plane as that of the ferroelectric coated and sintered crystal film 112a.

Furthermore, when the formation of the ferroelectric film 112 is carried out by forming the ferroelectric coated and sintered crystal film 112a on the first Sr(Ti₁₋ₓRuₓ)O₃ film through the use of a method of coating a solution, and after that, forming the ferroelectric crystal film 112b by a sputtering method, the composition of the surface and the whole of the ferroelectric film 112 can be made almost uniform as compared with the case where a ferroelectric film is formed on the first Sr(Ti₁₋ₓRuₓ)O₃ film by a sputtering method. Namely, in the ferroelectric film 112, the film composition can be made almost uniform irrespective of the film surface and film inside. As the result, piezoelectric properties of the ferroelectric film 112 can be enhanced.

Moreover, when forming the ferroelectric coated and sintered crystal film 112a through the use of a method of coating a solution, and after that, forming the ferroelectric crystal film 112b by a sputtering method, a polling effect can be obtained in the sputtering, and thus there is an advantage that polling processing is not required to be performed on the ferroelectric film 112.

In addition, as described above, heat of 650° C. or more is added to the ferroelectric coated and sintered crystal film 112a formed by a method of coating a solution, and heat of 500° C. is added to the ferroelectric crystal film 112b formed by a sputtering method. Accordingly, if the ferroelectric crystal film 112b and the ferroelectric coated and sintered crystal film 112a are formed in reverse order as compared with the present embodiment, the polling effect given by the initial sputtering method disappears due to the reversal of thermal history and there are caused disadvantages that the element of the ferroelectric crystal film 112b first formed diffuses thermally by the heat of 650° C. or more in forming afterwards the ferroelectric coated and sintered crystal film 112a to thereby lower the breakdown voltage of the ferroelectric crystal film 112b, and that cracks may be generated in the ferroelectric crystal film 112b.

In contrast to this, in the present embodiment, first the ferroelectric coated and sintered crystal film 112a is formed using a method of coating a solution, and after that, the ferroelectric crystal film 112b is formed by a sputtering method, and thus there is no reversal of thermal history and the performance of the ferroelectric film 112 can be enhanced.

Even when the d31 constant of a ferroelectric film is large, the ferroelectric film cannot always be used as a sensor. The fact that a d31 is large means literally that a displacement magnitude per 1 V is large, and it can be said that the ferroelectric film is easily used for an actuator. When a film is to be used for a sensor, the piezoelectric output constant g31 needs to be large. The G constant is given by d/εr, that is, is a value obtained by dividing the d constant by relative permittivity εr, which means that how many charges can be extracted when a PZT receives stress and is strained.

Namely, it is important to suppress the Er to be small simultaneously while extracting the d constant as much as possible. In order to draw out such properties, it is preferable to form a good interface by producing crystalline nuclei through the use of a sol-gel film having, for example, a thickness of 100 nm and by covering the entire substrate with a liquid and achieving crystallization, and to enhance the adherence of a sputtered film positioned in the upper portion of the interface. Due to the existence of a sol-gel PZT film having a good interface, the breakdown voltage becomes 180 V, which is three times or more as compared with the case of a sputtered PZT having the same film thickness. Furthermore, as the result of the existence of the sol-gel PZT film, a film of excellent quality can be obtained even when the temperature of film formation of the sputtered PZT in the upper portion thereof is lowered by 25° C. or more as compared with the conventional cases. Obviously, the lowering of the formation temperature of the entire film means the lowering of thermal stress, which leads to the reduction of the amount of residual strain of the entire film.

Note that, in the specification, the “d31” corresponds to the case, for example, where an electric field is applied to a PZT film in the direction perpendicular to the substrate surface and moves the PZT film in the parallel direction relative to the substrate surface.

### Example

Hereinafter, production methods of samples of the Example will be explained.

The formation of an oxide film and a Pt film is carried out on a 4-inch Si wafer 11 by an electron beam evaporation method to thereby give a film oriented in (100). Next, a Pt film of about 100 nm oriented in (100) is formed on the film, by a sputtering method. Then, a SrRuO₃ film oriented in (001) is formed on the Pt film, by a sputtering method.

Next, a PZT precursor solution is prepared. The PZT precursor solution is a precursor solution containing a metal compound containing, in an organic solvent, the whole of or a part of constituent metals of a PZT crystal and a partial polycondensation product thereof, and is a solution having a concentration of 25 wt % of PZT (Zr/Ti=52/48) and having 20%-excessive Pb.

Then, by coating, on the Pt film, the PZT precursor solution by a spin coating method, a first layer coated film is formed on the Pt film in a superimposed state. Specifically, 500 μL of the PZT precursor solution was coated at 5000 rpm for 10 sec.

Subsequently, the coated PZT precursor solution was dried by being held for 30 sec while being heated at 150° C. on a hot plate and thus moisture was removed, and after that, the resultant precursor solution was temporarily calcined by being held for 60 sec while being heated at 550° C. on a hot plate kept at a higher temperature.

A PZT amorphous precursor film of three layers including a ferroelectric material was generated by repeating the spin coating, drying and temporary calcination three times.

After that, an annealing treatment was performed on the PZT amorphous precursor film after the temporary calcinations by being held at a temperature of 650° C. for 1 min in an oxygen atmosphere of 10 atm through the use of a pressurized lamp annealing apparatus (RTA: rapidly thermal anneal), to thereby crystallize the PZT. After that, post annealing was performed at 900° C. for 5 sec. The crystallized PZT film (hereinafter, also referred to as a “spin-coated PZT film”) corresponds to the ferroelectric coated and sintered crystal film 112a shown in FIG. 1, has a perovskite structure and a thickness of 100 nm. Such sample was produced in plural number.

Then, PZT films (Y-1, -2 and -3) of a Zr rich composition, each having a thickness of 2.5 μm were formed by sputtering with PZT targets (Zr/Ti=60/40, 55/45 and 50/50) while changing continuously the PZT targets (temperature of 450° C.) (a PZT film corresponding to the ferroelectric crystal film 112b (hereinafter, also referred to as a “sputtered PZT film”)). Namely, the sample Y-1 of the composition (Zr/Ti=60/40), the sample Y-2 of the composition (Zr/Ti=55/45), and the sample Y-3 of the composition (Zr/Ti=50/50) were produced. All the films of these samples were (001) single-oriented PZT film as shown in FIG. 2. Note that, FIG. 2 is a drawing showing results of evaluating the crystallinity of the spin-coated PZT film of the sample in Example and the sputtered PZT film formed thereon, by XRD (X-Ray Diffraction). In FIG. 2, the vertical axis shows intensity and the horizontal axis shows 28.

As shown in FIG. 2, it was confirmed that the spin-coated PZT film and the sputtered PZT film had very excellent crystallinity.

Next, the composition of the entire spin-coated PZT film and sputtered PZT film was obtained by actually measuring the average composition of the PZT film by ICP (Inductively Coupled Plasma) analysis. The result thereof is as follows.

Pb: 81.3 wt %

Zr: 13.2 wt %

Ti: 6.82 wt %

The composition of an extreme film surface of the sputtered PZT film was obtained by extremely minute surface composition analysis based on SIMS (Secondary Ion Mass Spectrometry). The result is as follows.

Pb: 81.5 wt %

Zr: 12.9 wt %

Ti: 6.66 wt %

According to the above-described analysis results, it was found that, in the case of the sputtered/sol-gel film in the Example, the film composition did not vary at all in the film. Namely, compositions of the film surface and the entire film were almost uniform and the film composition was uniform irrespective of the film surface or inside of the film.

Furthermore, according to the Example, the spin-coated PZT film and the sputtered PZT film each having very excellent crystallinity were able to be obtained by forming a spin-coated PZT film having a thickness of 100 nm at the crystallization temperature of 650° C., and after that, forming a sputtered PZT film having a thickness of 2.5 μm at a substrate temperature of 450° C.

As a Comparative Example, there was produced a sample Y-2′ in which a sputtered PZT film having a thickness of 2.5 μm was formed at a substrate temperature of 450° C. without the formation of a spin-coated PZT film (no sol-gel initial nuclei). The uppermost surface of the 2.5 μm PZT film gave the result of Pb=105 and Zr/Ti=60/40, and the result of surface analysis in dissolving the film up to 200 nm close to the lower Pt electrode gave a Ti composition as rich as Pb 120% and Zr/Ti=45/55. A film average value measured by ICP for comparison was Pb=110 and Zr/Ti=55/45. In the sputtered PZT film of the sample in the Comparative Example, no perovskite phase existed and only a pyrochlore phase existed.

Subsequently, the film composition of the sample Y-2 with sol-gel initial nuclei according to the Example was evaluated. First, the uppermost surface of the 2.5 μm PZT film gave the result of Pb=108 and Zr/Ti=55/45, and the result of surface analysis in dissolving the film up to 200 nm close to the lower Pt electrode gave Pb 108% and Zr/Ti=55/45, which agreed well with the target composition. The film composition was extremely uniform. Furthermore, the average value of the film measured by ICP was Pb=110 and Zr/Ti=55/45. The composition of 52/48 of the initial nuclei sol-gel PZT did not give any influence since the thickness of the sputtered PZT film was as large as 2.5 μm.

From the Comparative Example, it was confirmed that a PZT film with excellent crystallinity was obtained in the Example because the spin-coated PZT film was formed before the formation of the sputtered PZT film.

Furthermore, the spin-coated PZT film and the sputtered PZT film according to the Example have the polling effect even without performing polling processing.

TABLE 1

| No. | 1 | 2 | 3 | 4 | 5 | 6 | 7 |
|---|---|---|---|---|---|---|---|
| Sample ID | Y-1 | Y-2 | Y-3 | Y-4 | Y-5 | COMMERCIALLY | COMMERCIALLY |
| | | | | | | AVAILABLE-1 | AVAILABLE-2 |
| PZT Tick(um) | 2.6 | 2.5 | 2.5 | 1.12 | 1.1 | BULK | BULK |
| Zr/Ti RATIO | 58/42 | 55/45 | 53/47 | 50/50 | 45/55 | 52/48 | 55/45 |
| ORIENTATION | (001) | (001) | (001) | (001) | (001) | RANDOM | RANDOM |
| | SINGLE | SINGLE | SINGLE | SINGLE | SINGLE | | |
| εr | 297 | 411 | 700 | 550 | 387 | 1946 | 593 |
| d31 (pm/V) | 116.0 | 120.0 | 150.0 | 145.0 | 120.0 | 197.0 | 24.0 |
| ±2 V@700 Hz | | | | | | | |
| g31 (Vm/N) × 10⁻³ | 53.4 | 29.2 | 21.4 | 26.4 | 31.0 | 10.1 | 4.0 |

Results of evaluating piezoelectric properties of soft-series PZT thin films (Y-1, -2 and -3) and hard-series PZT thin films (Y-4 and -5) are shown in Table 1. In the case of (001) single-oriented PZT, in contrast to commercially bulk PZT in Comparative Example, the d31 does not become remarkably small even when a Zr/Ti ratio largely shifts from MPB, but the relative permittivity largely lowers. Accordingly, it is known that, when a thick film having a thickness of 2.5 to 5 μm is necessary for sensor applications, the use of Zr rich soft-series PZT gives sufficient compatibility, and in the case of a sensor requiring a film thickness of 1 m or less, the use of the hard-series PZT of the present invention gives sufficient compatibility.

In the case of a bulk, when a film composition is shifted from MPB in order to lower the relative permittivity, the d31 constant is also attenuated, and thus it is very hard to use the bulk.

The PZT thin film of the Example is single-oriented PZT in (001), and even when the film composition is shifted from MPB, the relative permittivity can be largely lowered without lowering the piezoelectric d31 constant, and as the result, it becomes possible to make the piezoelectric g31 constant as large as 25×10⁻³ Vm/N or more.

Furthermore, the sol-gel initial nuclei create a good interface to give excellent breakdown voltage, and thus Y-1, -2 and -3 were not broken even at 200 V and the breakdown voltage of Y-4 and -5 was as high as 120 V, which far surpassed 50 V of the sputtered PZT film.

When the PZT thin film Y-1 in the Example is subjected to post-annealing at 850° C. for 1 min, the breakdown voltage lowered to 100 V. (Although the value is still sufficiently higher than that of the sputtered film), the sputtered film was formed at 500° C. and the post-annealing temperature is much higher than the temperature at the time of PZT formation, and thus it is considered that some kind of thermal stress remained in the film to thereby lower the breakdown voltage.

Namely, also from this, it is very reasonable to use the sol-gel PZT that requires a temperature as high as 650° C., as initial nuclei and to grow, on the upper parts of sol-gel PZT, the sputtered PZT whose formation temperature is as low as 450° C. or 500° C. However, piezoelectric properties largely different from those of a bulk can have been obtained and this matter cannot easily be analogized from Patent Literature 1.

Note that, since both d31 and g31 relate to a movement of being depressed, values represented in Table 1 are fundamentally accompanied by a minus sign (such as −120 μm/V). However, irrespective of ±, the magnification of the constant is determined by the absolute value thereof, and considering that a minus sign makes the situation obscure, no minus sign is given in the present specification. For example, in the case of −120 μm/V, since with a minus sign, the thin film moves by 120 μm per 1 V of applied voltage, in the depressing direction. Furthermore, in the case of 150 μm/V, the thin film moves by 150 μm per 1 V of applied voltage, in the protruding direction.

Note that, in the present specification, the precursor solution means any of a sol-gel solution, an MOD (Metal Organic Decomposition) solution and a mixed solution of a sol-gel solution and an MOD solution.

Hereinafter, detailed explanation will be given.

A sol-gel solution is obtained by hydrolyzing and then polymerizing a metal alcoxide or the like to put it into a colloidal state, and after that, by dispersing the resultant colloid in a solution of an organic solvent such as alcohol. A solution in which the main component itself forms a precursor of a ceramic is particularly referred to as a sol-gel solution.

On the other hand, a solution obtained by dissolving a metal organic salt in an organic solvent is generally referred to as an MOD solution. Generally, acetic acid, octylic acid, hexanoic acid, valeric acid, carboxylic acid, butyric acid, trifluoric acid or the like is used as an organic acid.

In addition, as one aspect of the present invention, there are many cases where a sol-gel solution and an MOD solution are used as a mixture, and in that case, the nominal designation is determined depending on the main component, or the like.

As described above, in the case of one aspect of the present invention, a solution formed of the mixture of both is used, and, since the most part thereof is formed of a polycondensation product of alcoxide (a precursor of ceramics), a solution containing, in an organic solvent, a metal compound including all of or a part of constituent metals and a partial polycondensation product thereof (precursor) is referred to as a precursor solution.

### DESCRIPTION OF REFERENCE SYMBOLS

101 substrate
102 Pt film
103 PZT film
112 ferroelectric film
112a ferroelectric coated and sintered crystal film
112b ferroelectric crystal film

1. A ferroelectric film, comprising:
a ferroelectric coated and sintered crystal film; and
a ferroelectric crystal film formed on said ferroelectric coated and sintered crystal film, by a sputtering method,
wherein
said ferroelectric coated and sintered crystal film is formed by coating a solution including a metal compound containing, in an organic solvent, all of or a part of constituent metals of said ferroelectric crystal film and a partial polycondensation product thereof and by heating the same to be crystallized.

2. The ferroelectric film according to claim 1, wherein each of said ferroelectric coated and sintered crystal film and said ferroelectric crystal film is a Pb(Zr,Ti)O₃ film or a (Pb,A)(Zr,Ti)O₃ film, and A includes at least one kind selected from the group consisting of Li, Na, K, Rb, Ca, Sr, Ba, Bi and La.

3. The ferroelectric film according to claim 2, wherein, when a result of SIMS analysis of a composition of a surface of said ferroelectric crystal film gives a Pb content of P₁ mol %, a Zr content of Z₁ mol % and a Ti content of T₁ mol % and a result of ICP analysis of a total composition of said ferroelectric coated and sintered crystal film and said ferroelectric crystal film gives a Pb content of P₂ mol %, a Zr content of Z₂ mol % and a Ti content of T₂ mol %, the contents satisfy formulae 1 to 3 below,
0.8×P₂≦P₁≦1.2×P₂ formula 1
0.8×Z₂≦Z₁≦1.2×Z₂ formula 2
0.8×T₂≦T₁≦1.2×T₂ formula 3.

4. The ferroelectric film according to claim 2, wherein:
a total thickness of said ferroelectric coated and sintered crystal film and said ferroelectric crystal film is from 0.5 μm or more to less than 1.75 μm; and
a composition ratio of Zr to Ti in the whole of said ferroelectric coated and sintered crystal film and said ferroelectric crystal film satisfies a formula 4 below,
51/49≧Zr/Ti≧40/60 formula 4.

5. The ferroelectric film according to claim 2, wherein:
a total thickness of said ferroelectric coated and sintered crystal film and said ferroelectric crystal film is from 1.75 μm or more to 5 μm or less; and
a composition ratio of Zr to Ti in the whole of said ferroelectric coated and sintered crystal film and said ferroelectric crystal film satisfies a formula 5 below,
54/46≦Zr/Ti≦60/40 formula 5.

6. The ferroelectric film according to claim 5, wherein a total thickness of said ferroelectric coated and sintered crystal film and said ferroelectric crystal film is 3.5 Um or less.

7. The ferroelectric film according to claim 1, wherein said ferroelectric coated and sintered crystal film has a thickness of 20 nm or more to less than 500 nm.

8. The ferroelectric film according to claim 1, wherein said ferroelectric crystal film is oriented in a same plane as that of said ferroelectric coated and sintered crystal film.

9. A manufacturing method of a ferroelectric film, comprising the steps of:
forming an amorphous precursor film by a method of coating a solution;
forming a ferroelectric coated and sintered crystal film, by heating said amorphous precursor film in an oxygen atmosphere to thereby oxidize and crystallize said amorphous precursor film; and
epitaxially growing and forming a ferroelectric crystal film on said ferroelectric coated and sintered crystal film, by a sputtering method, wherein said solution is a solution containing, in an organic solvent, a metal compound including all of or a part of constituent metals of said ferroelectric crystal film and a partial polycondensation product thereof.

10. The manufacturing method of a ferroelectric film according to claim 9, wherein each of said ferroelectric coated and sintered crystal film and said ferroelectric crystal film is a Pb(Zr,Ti)O₃ film or a (Pb,A)(Zr,Ti)O₃ film, and A includes at least one kind selected from the group consisting of Li, Na, K, Rb, Ca, Sr, Ba, Bi and La.

11. The manufacturing method of a ferroelectric film according to claim 10, when a result of SIMS analysis of a composition of a surface of said ferroelectric crystal film gives a Pb content of P₁ mol %, a Zr content of Z₁ mol % and a Ti content of T₁ mol % and a result of ICP analysis of a total composition of said ferroelectric coated and sintered crystal film and said ferroelectric crystal film gives a Pb content of P₂ mol %, a Zr content of Z₂ mol % and a Ti content of T₂ mol %, the contents satisfy formulae 1 to 3 below,
0.8×P₂≦P₁≦1.2×P₂ formula 1
0.8×Z₂≦Z₁≦1.2×Z₂ formula 2
0.8×T₂≦T₁≦1.2×T₂ formula 3.

12. The manufacturing method of a ferroelectric film according to claim 10, wherein a temperature in forming said ferroelectric crystal film by a sputtering method is lower than a temperature in oxidizing and crystallizing said amorphous precursor film, by 150° C. or more.

13. The manufacturing method of a ferroelectric film according to claim 10, wherein:
a total thickness of said ferroelectric coated and sintered crystal film and said ferroelectric crystal film is from 0.5 μm or more to less than 1.75 μm; and
a composition ratio of Zr to Ti in the whole of said ferroelectric coated and sintered crystal film and said ferroelectric crystal film satisfies a formula 4 below,
51/49≧Zr/Ti≧40/60 formula 4.

14. The manufacturing method of a ferroelectric film according to claim 10, wherein:
a total thickness of said ferroelectric coated and sintered crystal film and said ferroelectric crystal film is from 1.75 μm or more to 5 μm or less; and
a composition ratio of Zr to Ti in the whole of said ferroelectric coated and sintered crystal film and said ferroelectric crystal film satisfies a formula 5 below,
54/46≦Zr/Ti≦60/40 formula 5.

15. The manufacturing method of a ferroelectric film according to claim 14, wherein a total thickness of said ferroelectric coated and sintered crystal film and said ferroelectric crystal film is 3.5 μm or less.

16. The manufacturing method of a ferroelectric film according to claim 9, wherein a thickness of said ferroelectric coated and sintered crystal film is from 20 nm or more to less than 500 nm.

17. The manufacturing method of a ferroelectric film according to claim 9, wherein said ferroelectric coated and sintered crystal film is oriented in a same plane as that of said ferroelectric crystal film.
